(19) United States
(12) Patent Application Publication
(10) Pub. No.: US 2026/0130177 A1
(43) Pub. Date: May 7, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Chien-Ting Lin, Tainan City (TW); Chuan-Lan Lin, Chiayi city (TW); Chu-Fu Lin, Kaohsiung City (TW)

(73) Assignee: UNITED MICROELECTRONICS CORP., Hsin-Chu City (TW)

(21) Appl. No.: 18/973,090

(22) Filed: Dec. 8, 2024

(30) Foreign Application Priority Data
Nov. 5, 2024 (TW) 113142232

(51) Int. Cl. H01L 23/00; H01L 21/3105; H01L 21/66; H01L 21/768; H01L 23/538

(52) U.S. Cl. CPC H10P 74/273; H10W 20/089; H10W 70/611; H10W 70/65; H10P 95/06; H10W 72/01971; H10W 72/90; H10W 72/934; H10W 72/9415; H10W 72/952

(57) ABSTRACT

A method for fabricating a semiconductor device includes the steps of first forming a first inter-metal dielectric ((IMD) layer on the substrate and a first metal interconnection in the first IMD layer, forming a bonding pad on the first IMD layer, forming a passivation layer on the bonding pad, removing part of the passivation layer to expose the bonding pad, performing a chip probing test on the bonding pad, removing the bonding pad to form a recess, forming a dielectric layer to fill the recess completely, and forming a second metal interconnection in the dielectric layer.

### BACKGROUND OF THE INVENTION

### 1. Field of the Invention

The invention relates to a method for fabricating semiconductor device, and more particularly to a method of removing bonding pad after performing a chip probing test on the bonding pad.

### 2. Description of the Prior Art

The semiconductor industry has experienced rapid growth due to continuous improvements in the integration density of various electronic components (i.e., transistors, diodes, resistors, capacitors, etc.). For the most part, this improvement in integration density has come from continuous reductions in minimum feature size, which allows more of the smaller components to be integrated into a given area. These smaller electronic components also demand smaller packages that utilize less area than previous packages. Some smaller types of packages for semiconductor components include quad flat packages (QFPs), pin grid array (PGA) packages, ball grid array (BGA) packages, flip chips (FC), three-dimensional integrated circuits (3DICs), wafer level packages (WLPs), and package on package (PoP) devices and so on.

3DICs provide improved integration density and other advantages, such as faster speeds and higher bandwidth, because of the decreased length of interconnects between the stacked chips. However, there are quite a few challenges to be handled for the technology of 3DICs.

### SUMMARY OF THE INVENTION

According to an embodiment of the present invention, a method for fabricating a semiconductor device includes the steps of first forming a first inter-metal dielectric ((IMD) layer on the substrate and a first metal interconnection in the first IMD layer, forming a bonding pad on the first IMD layer, forming a passivation layer on the bonding pad, removing part of the passivation layer to expose the bonding pad, performing a chip probing test on the bonding pad, removing the bonding pad to form a recess, forming a dielectric layer to fill the recess completely, and forming a second metal interconnection in the dielectric layer.

According to another aspect of the present invention, a semiconductor device includes a substrate having a first region and a second region, a first inter-metal dielectric ((IMD) layer on the first region and the second region, a first metal interconnection in the first IMD layer of the first region, a dielectric layer on the first metal interconnection, wherein the dielectric layer comprises a reverse T-shape, and a passivation layer on the first IMD layer and around the dielectric layer.

According to yet another aspect of the present invention, a semiconductor device includes a first inter-metal dielectric ((IMD) layer on a substrate, a first metal interconnection in the first IMD layer, a bonding pad on the first metal interconnection, a dielectric layer on the bonding pad, and a passivation layer around the bonding pad and the dielectric layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 illustrate a method for fabricating a semiconductor device according to an embodiment of the present invention.

FIG. 7 illustrates a structural view of a semiconductor device according to an embodiment of the present invention.

FIGS. 8-10 illustrate a method for fabricating a semiconductor device according to an embodiment of the present invention.

FIG. 11 illustrates a structural view of a semiconductor device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

Referring to FIGS. 1-6, FIGS. 1-6 illustrate a method for fabricating a semiconductor device according to an embodiment of the present invention. As shown in FIG. 1, a substrate 12 made of semiconductor material is provided. Preferably, the substrate 12 could be made of semiconductor substrate material including but not limited to for example silicon substrate, epitaxial silicon substrate, silicon carbide substrate or even a silicon-on-insulator (SOI) substrate, which are all within the scope of the present invention. In this embodiment, the substrate 12 could be used for fabricating elements including MV devices, HV devices, pixel circuits, LV devices for LV driving circuits, and/or graphics process unit (GPU).

Next, a front end of line (FEOL) and a back end of line (BEOL) fabrication processes could be conducted on the wafers 12, 14 respectively while the wafer 12 is adhered onto the carrier 18. In this embodiment, the FEOL process could include the process of forming metal-oxide semiconductor (MOS) transistors, oxide semiconductor field effect transistors (OS FETs), fin field effect transistor (FinFETs), or other active devices and/or passive devices. BEOL process on the other hand could include forming metal interconnect structures such as metal inter-metal dielectric (IMD) layers and metal interconnections on the aforementioned active devices and/or passive devices.

If a MOS transistor were to be fabricated, the FEOL process could include the steps of forming a gate structure on the substrate, forming a spacer (not shown) adjacent to sidewalls of the gate structure and a source/drain region in the substrate adjacent to two sides of the spacer, in which the gate structure could include polysilicon or metal, the spacer could include dielectric material such as silicon oxide or silicon nitride, and the source/drain region could include p-type dopants or n-type dopants depending on the conductive type of the transistor being fabricated.

Next, an interlayer dielectric (ILD) layer could be formed on the substrate to cover the MOS transistor or other active devices, and then a contact plug formation and metal interconnect process from BEOL process could be conducted to form a plurality of contact plugs in the ILD layer for connecting the source/drain region and the gate structure, an inter-metal dielectric (IMD) layer disposed on the ILD layer, and metal interconnections 14 in the IMD layer for connecting the contact plugs, in which the topmost metal interconnection 14 on front side of the substrate 12 could be used as connecting junctions such as direct bond interconnects (DBIs) as the two wafers could be bonded through DBIs in the later process. In this embodiment, the ILD layer and the IMD layer could include oxides including but not limited to for example tetraethyl orthosilicate (TEOS) and the contact plugs and the metal interconnections 14 could include Al, Cr, Cu, Ta, Mo, W, or combination thereof.

Next, another metal interconnection 16 is formed on the metal interconnection 14 and an IMD layer 18 is formed around the metal interconnection 14. For instance, an IMD layer 18 could be formed to cover the metal interconnection 14 entirely, a photo-etching process is conducted to remove part of the IMD layer 18 for forming a plurality of contact holes (not shown), a metal layer (not shown) is formed to not only fill the contact holes completely but also extended to a top surface of the IMD layer 18, and then another photo-etching process is conducted to remove part of the metal layer. Preferably the patterned metal layer in the IMD layer 18 becomes the metal interconnection 16 as the patterned metal layer above the metal interconnection 16 and IMD layer 18 becomes a bonding pad 20.

Next, a passivation layer 22 is formed on the bonding pad 20 to cover the IMD layer 18 and bonding pad 20 entirely, and then an etching process is conducted to remove part of the passivation layer 20 so that the remaining passivation layer 20 still covers the edge portion surface of part of the bonding pad 20 and exposes the surface of the bonding pad 20 on the central portion.

According to an embodiment of the present invention, the IMD layer 18 could include silicon oxide and/or silicon nitride, the passivation layer 22 includes plasma enhanced oxide (PEOX), the metal interconnection 14 below includes copper (Cu), and the metal interconnection 16 and bonding pad 20 include same material such as aluminum (Al). According to other embodiment of the present invention, the metal interconnection 16 and bonding pad 20 could include same material but different from the metal interconnection 14 underneath while the three elements 14, 16, 20 could all include copper (Cu), silver (Ag), gold (Au), nickel (Ni), tungsten (W), or combination thereof.

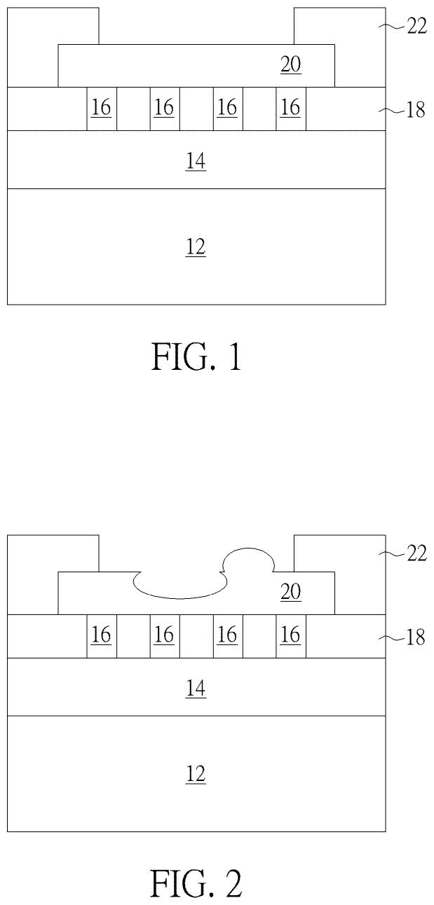

Next, as shown in FIG. 2, a chip probe test is conducted on the bonding pad 20 by using a chip probe to test performance and/or functionality of the chip through the exposed bonding pad 20. According to an embodiment of the present invention, the surface of the bonding pad 20 after tested by chip probe is likely to transform form a flat or planar surface into a non-planar or irregular surface having protruding and/or indenting profiles.

Next, as shown in FIG. 3, an etching process could be conducted with or without using a patterned mask to completely remove the bonding pad 20 for forming a recess 24, in which the recess 24 exposes the metal interconnection 16 underneath as the width of the recess 24 closer to the metal interconnection 16 is slightly greater than the width of the recess 24 away from the metal interconnection 16. In other words, the recess 24 preferably has a substantially reverse T-shape cross-section at this stage.

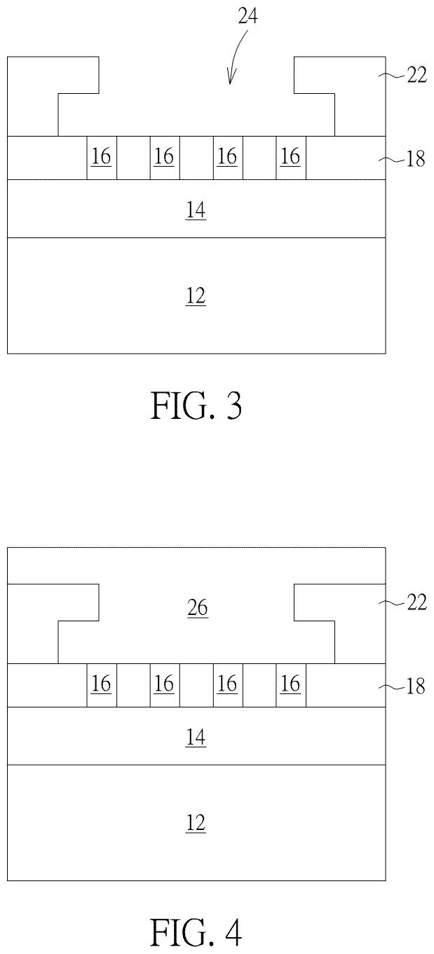

Next, as shown in FIG. 4, a dielectric layer 26 is formed in the recess 24 to fill the recess 24 completely while disposed on sidewalls and top surface of the passivation layer 22 on two adjacent sides. Preferably, the dielectric layer 26 and the passivation layer 22 could be made of same or different material. For instance, the dielectric layer 26 is preferably made of silicon oxide in this embodiment, nevertheless, according to other embodiment of the present invention, the dielectric layer 26 and the passivation layer 22 could also include silicon oxide, silicon nitride, or combination thereof.

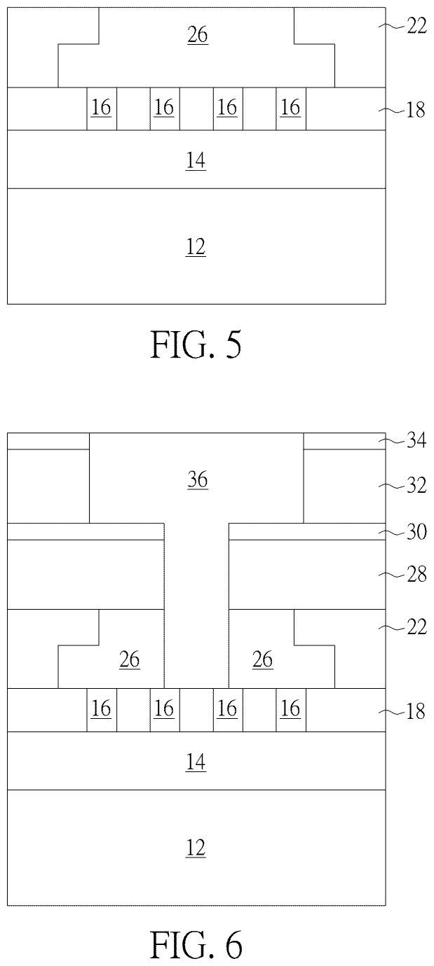

Next, as shown in FIG. 5, a planarizing process such as a chemical mechanical polishing (CMP) process is conducted to remove part of the dielectric layer 26 so that top surface of the remaining dielectric layer 26 is even with the top surface of the passivation layer 22. Since the aforementioned recess 24 has a substantially reverse T-shape cross-section, the dielectric layer 26 formed to fill the recess 24 completely at this stage also includes a reverse T-shape cross-section while the passivation layer 22 adjacent to each side of the dielectric layer 26 includes a L-shape cross-section.

Next, as shown in FIG. 6, additional IMD layers and metal interconnections could be formed on the dielectric layer to serve as direct bond interconnections (DBIs) depending on the demand of the process. For instance, one or multiple IMD layers 28, 32 and stop layers 30, 34 could be formed on the passivation layer 22 and dielectric layer 26 and then one or more photo-etching processes could be conducted to remove part of the IMD layers 28, 32, part of the stop layers 30, 34, and part of the dielectric layer 26 for forming a contact hole (not shown). Next, conductive materials are deposited into the contact hole along with a planarizing process such as CMP to form a metal interconnection 36 connecting the metal interconnection 16 underneath.

According to an embodiment of the present invention, the metal interconnection 36 could be embedded within the IMD layers 28, 32 according to a single damascene process or dual damascene process. For instance, the metal interconnection 36 could further includes a barrier layer and a metal layer, in which the barrier layer could be selected from the group consisting of titanium (Ti), titanium nitride (TiN), tantalum (Ta), and tantalum nitride (TaN) and the metal layer could be selected from the group consisting of tungsten (W), copper (Cu), aluminum (Al), titanium aluminide (TiAl), and cobalt tungsten phosphide (CoWP), but not limited thereto.

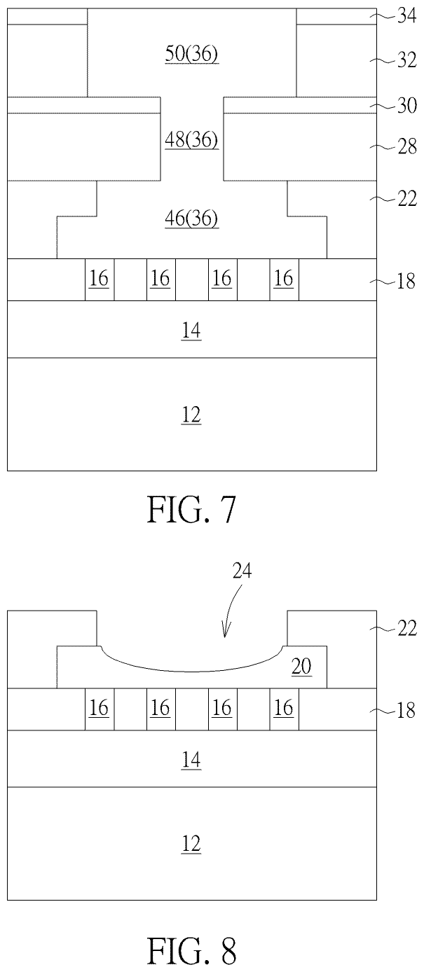

Referring to FIG. 7, FIG. 7 further illustrates a structural view of a semiconductor device according to an embodiment of the present invention. As shown in FIG. 7, in contrast to the metal interconnection 36 in FIG. 6 include a T-shape cross-section, it would also be desirable to first conduct a dry etching process to remove part of the IMD layers 28, 32, part of the stop layers 30, 34, and part of the dielectric layer 26, conduct a wet etching process to remove the dielectric layer 26 completely for forming a contact hole, and then deposit conductive materials such as the aforementioned barrier layer and metal layer along with a planarizing process for forming a metal interconnection 36. In this embodiment, the metal interconnection 36 includes two horizontal portions 46, 50 and a vertical portion 48 connecting the horizontal portions 46, 50, in which the bottom horizontal portion 46 further includes a wider portion directly contacting the metal interconnection 16 and a narrower portion connecting the vertical portion 48.

Referring to FIGS. 8-10, FIGS. 8-10 illustrate a method for fabricating a semiconductor device according to an embodiment of the present invention. As shown in FIG. 8, it would be desirable to conduct an etching process to remove part of the bonding pad 20 without removing the bonding pad 20 completely after a chip probe test shown in FIG. 2 is conducted on the exposed bonding pad 20 so that the remaining bonding pad 20 still covers the surface of the IMD layer 18 and metal interconnection 16. In this embodiment, after removing the uneven protrusions, the top surface of the remaining bonding pad 20 not shielded by the passivation layer 22 preferably includes a curve or curved surface having no protrusions and/or no indentations. The top surface of the bonding pad 20 adjacent to two sides of the curve directly under the passivation layer 22 on the other hand includes a planar surface due to coverage of the passivation layer 22.

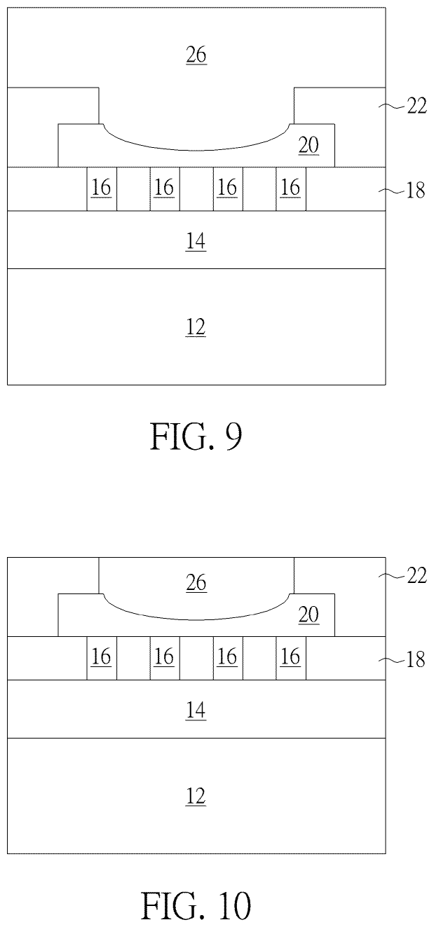

Next, as shown in FIG. 9, a dielectric layer 26 is formed in the recess 24 to fill the recess 24 completely and dispose on sidewalls and top surface of the passivation layer 22. Preferably, the dielectric layer 26 includes silicon oxide, but not limited thereto.

Next, as shown in FIG. 10, a planarizing process such as a chemical mechanical polishing (CMP) process is conducted to remove part of the dielectric layer 26 so that top surface of the remaining dielectric layer 26 is even with the top surface of the passivation layer 22. Since the bottom surface of the aforementioned recess 24 has a curved surface, the bottom surface of the dielectric layer 26 filled into the recess 24 also includes a curve. Similar to the aforementioned embodiment, the dielectric layer 26 and the passivation layer 22 could be made of same or different material. For instance, the dielectric layer 26 and the passivation layer 22 could all include silicon oxide, silicon nitride, or combination thereof.

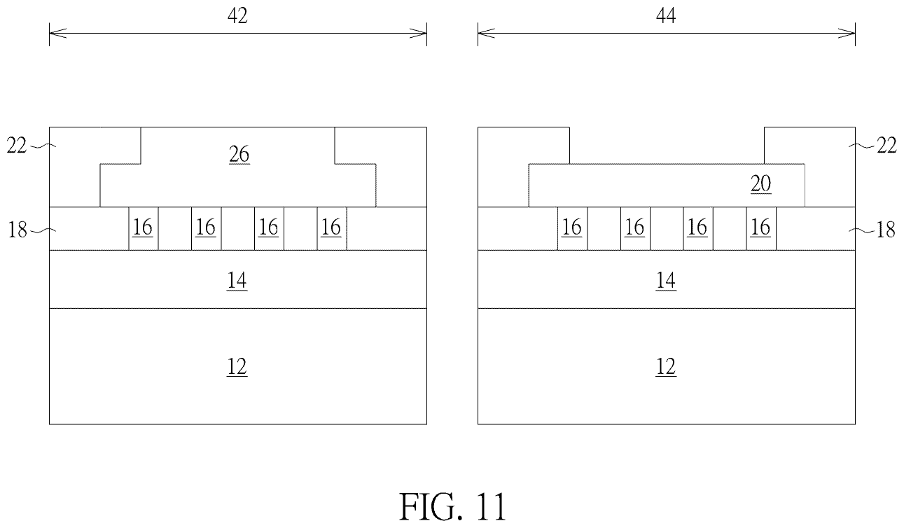

Referring to FIG. 11, FIG. 11 illustrates a structural view of a semiconductor device according to an embodiment of the present invention. As shown in FIG. 11, the present invention could also provide a substrate 12 having a first region 42 and a second region 44, in which the first region 42 being a chip probe test region while the second region 44 being a non-chip-probe test region or a bonding pad region In other words, the first region 42 includes a structure that has been completed a chip probe test as shown in FIGS. 5-9 while the second region 44 includes a bonding pad structure that has not been tested under a chip probe test.

Taking the structure completed by a chip probe test in FIG. 5 as an example, the semiconductor structure could include a metal interconnection 16 disposed in the IMD layer 18 on the first region 42 and second region 44, a patterned dielectric layer 26 disposed on the metal interconnection 16 on the first region 42, a bonding pad 20 disposed on the metal interconnection 16 on the second region 44, and a passivation layer 22 disposed on the IMD layer 18 on both first region 42 and second region 44 to surround the dielectric layer 26 and the bonding pad 20.

Preferably, the bottom surface of the dielectric layer 26 on the first region 42 is even with the bottom surface of the bonding pad 20 on the second region 44, the dielectric layer 26 on the first region 42 includes a reverse T-shape cross-section, and each passivation layer 22 on the dielectric layer 26 and bonding pad 20 on each of the first region 42 and second region 44 includes a L-shape cross-section respectively.

Typically, surface of aluminum bonding pad 20 tested under chip probe for performance and/or efficiency is likely to remain uneven profiles such as protruding and/or indenting marks and these irregular surface marks often generate voids affecting the connecting quality between DBIs and bonding pads. To resolve this issue, the present invention could conduct a chip probe test and remove the entire bonding pad 20 that has been tested by etching and fill the recess with a dielectric layer 26 according to the processes addressed in FIGS. 1-5. Alternatively, the present invention could also remove only a portion of the tested bonding pad so that the top surface of the remaining bonding pad has a perfect curve without any protrusion or indentation, and then fill a dielectric layer onto the remaining bonding pad according to the processes addressed in FIGS. 8-10.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
forming a bonding pad on a substrate;
forming a passivation layer on part of the bonding pad;
performing a chip probing test on the bonding pad;
removing the bonding pad to form a recess; and
forming a dielectric layer in the recess.

2. The method of claim 1, further comprising:
forming a first inter-metal dielectric ((IMD) layer on the substrate and a first metal interconnection in the first IMD layer;
forming the bonding pad on the first IMD layer;
forming the passivation layer on the bonding pad;
removing part of the passivation layer to expose the bonding pad;
performing the chip probing test;
removing the bonding pad to form the recess;
forming the dielectric layer to fill the recess completely; and
forming a second metal interconnection in the dielectric layer.

3. The method of claim 2, further comprising removing the bonding pad to expose the first metal interconnection.

4. The method of claim 2, further comprising planarizing the dielectric layer after forming the dielectric layer in the recess.

5. The method of claim 1, wherein top surfaces of the passivation layer and the dielectric layer are coplanar.

6. The method of claim 1, wherein the recess comprises a reverse T-shape.

7. A semiconductor device, comprising:
a substrate having a first region and a second region;
a first inter-metal dielectric ((IMD) layer on the first region and the second region;
a first metal interconnection in the first IMD layer of the first region;
a dielectric layer on the first metal interconnection, wherein the dielectric layer comprises a reverse T-shape; and
a passivation layer on the first IMD layer and around the dielectric layer.

8. The semiconductor device of claim 7, further comprising:
the first metal interconnection in the first IMD layer on the second region;
a bonding pad on the first metal interconnection on the second region; and
the passivation layer on the first IMD layer and part of the bonding pad.

9. The semiconductor device of claim 7, wherein top surfaces of the dielectric layer and the passivation layer are coplanar.

10. The semiconductor device of claim 7, wherein the passivation layer comprise a L-shape.

11. The semiconductor device of claim 7, wherein the dielectric layer and the passivation layer comprise different materials.

12. A semiconductor device, comprising:
a first inter-metal dielectric ((IMD) layer on a substrate;
a first metal interconnection in the first IMD layer;
a bonding pad on the first metal interconnection;
a dielectric layer on the bonding pad; and
a passivation layer around the bonding pad and the dielectric layer.

13. The semiconductor device of claim 12, wherein a top surface of the bonding pad comprises a curve.

14. The semiconductor device of claim 12, wherein a bottom surface of the dielectric layer comprises a curve.

15. The semiconductor device of claim 12, wherein top surfaces of the dielectric layer and the passivation layer are coplanar.

16. The semiconductor device of claim 12, wherein the passivation layer comprise a L-shape.
